(19) United States
(12) Patent Application Publication
(10) Pub. No.: US 2014/0269046 A1
(43) Pub. Date: Sep. 18, 2014

(54) APPARATUSES AND METHODS FOR USE IN SELECTING OR ISOLATING MEMORY CELLS

(71) Applicant: Micron Technology, Inc., Boise, ID (US)

(72) Inventors: Luca Laurin, Lissone (IT); Augusto Benvenuti, Lallio (IT); Marco Riva, Lallio (IT)

(73) Assignee: MICRON TECHNOLOGY, INC., Boise, ID (US)

(21) Appl. No.: 14/077,726

(22) Filed: Nov. 12, 2013

Related U.S. Application Data
(60) Provisional application No. 61/798,158, filed on Mar. 15, 2013.

(51) Int. Cl. G11C 13/00; H01L 45/00

(52) U.S. Cl. CPC G11C 13/0021; H01L 45/06; G11C 13/0004
USPC 365/163; 257/2

(57) ABSTRACT

Methods and devices for selection and/or isolation of memory cells include use of a thyristor For example, a memory storage component may be selected for access, at least in part, by initiating application of a triggering potential to affect a gate of a thyristor that is coupled in series with a memory storage component. The gate of the thyristor connects to a memory cell word line and permits an efficient polarity scheme for selected and unselected memory array conductors to reduce leakage current relative to conventional selectors, such as bipolar junction transistors.

### PRIORITY CLAIM

This application is a nonprovisional application claiming the priority benefit of U.S. Provisional Application No. 61/798,158, filed Mar. 15, 2013.

### FIELD

Subject matter disclosed herein relates to memory devices and, more particularly, to apparatuses and methods for selecting or isolating memory cells.

### BACKGROUND

A memory device may comprise a plurality of memory cells. For example, a plurality of memory cells may be arranged in an array configuration and/or a stacked configuration. A memory device may also comprise an interface that may be used, for example, in accessing a memory storage component. For example, an interface may access a memory storage component to determine a programmed state of the memory cell, e.g., as part of a READ operation. An interface may also access a memory storage component to establish a programmed state in the memory cell, e.g., as part of a WRITE operation. An interface may, for example, be coupled to one or more other circuit devices (e.g., a processor, a transceiver, etc.), which may use a memory device.

In certain example instances, a memory device may be provided as a separate component (e.g., chip, semiconductor die, etc.) which may be coupled to other circuit devices. In certain other instances, a memory device may be provided along with one or more other circuit devices, for example, as part of multiple chip package, one or more semiconductor dies, a system on a chip, just to name a few.

In certain instances, a memory device may comprise a phase change memory (PCM). For example, a memory cell may comprise a PCM storage component (e.g., an ovonic memory switch (OMS) such as a chalcogenide component) and a selection component (e.g., a bipolar transistor, an ovonic threshold switch (OTS), etc.).

### BRIEF DESCRIPTION OF THE FIGURES

Non-limiting and non-exhaustive implementations will be described with reference to the following figures, wherein like reference numerals refer to like parts throughout the various figures unless otherwise specified.

FIG. 1 is a schematic diagram showing an example apparatus including a memory cell comprising a memory storage component (e.g., a PCM component, etc.) and a thyristor, according to an implementation.

FIG. 2 is a graph illustrating an example current-voltage characteristic of a thyristor, according to an implementation.

FIG. 3 is a schematic diagram showing an example thyristor circuit comprising an anode (A), a gate (G), and a cathode (K) that may be used in the memory device of FIG. 1, according to an implementation.

FIG. 4A is a schematic diagram showing an example thyristor circuit in the form of a 3-node silicon controlled rectifier (SCR) illustrated in a representative vertically formed stack in a PNPN layered semiconductor configuration that may be fabricated for use in the memory device of FIG. 1, according to an implementation.

FIG. 4B is a schematic diagram showing an example thyristor circuit in the form of a Thin Capacitively Coupled Thyristor (TCCT) illustrated in a representative vertically formed stack in a PNPN layered semiconductor configuration with an additional gate dielectric portion that may be fabricated for use in the memory device of FIG. 1, according to an implementation.

FIG. 5 is a diagram of an example method that may be used in the memory device of FIG. 1 to select and access a memory cell, according to an implementation.

FIG. 6 is a diagram of another example method that may be used in the memory device of FIG. 1 to select and access a memory storage component, according to another implementation.

FIG. 7 is a diagram of an example method that may be used in the memory device of FIG. 1 to selectively isolate a memory cell, according to an implementation.

FIG. 8 is an example state diagram for use in controlling a memory cell that may be selected and turned ON for access and turned OFF for isolation, according to an implementation.

FIGS. 9-11 are schematic diagrams showing example memory cells that may be used in the memory device of FIG. 1 and which comprise a memory storage component and a thyristor arranged according to certain alternative implementations.

FIG. 12 is a schematic diagram showing an example configuration of the memory cell with a metal word line conductor and a buried word line conductor.

FIG. 13 is a schematic diagram showing example memory cells including bipolar junction transistors as selectors, with the cells configured in a two by two (2×2) array.

FIG. 14 is a schematic diagram showing example memory cells including thyristors as selectors, with the cells configured in a two by two (2×2) array, according to an implementation.

FIG. 15 is an illustration depicting an isometric view of a portion of an example memory device including bipolar junction transistors as selectors.

FIGS. 16A and 16B are illustrations depicting cross-sectional views of an example memory device including bipolar junction transistors as selectors.

FIG. 17 is an illustration depicting an isometric view of a portion of an example memory device including thyristors as selectors, according to an implementation.

FIGS. 18A and 18B are illustrations depicting cross-sectional views of an example memory device including thyristors as selectors, according to an implementation.

### DETAILED DESCRIPTION

Reference throughout this specification to “one implementation,” “an implementation,” or “certain implementations” means that a particular feature, structure, or characteristic described in connection with a described implementation(s) may be included in at least one implementation of claimed subject matter. Thus, appearances of the phrase “in one example implementation,” “in an example implementation,” or “in certain example implementations” in various places throughout this specification are not necessarily all referring to the same implementation(s). Furthermore, particular features, structures, or characteristics may be combined in one or more implementations.

FIG. 1 is a schematic diagram showing an example apparatus 100 comprising an example memory device 116, according to an implementation. As shown, memory device 116 may be provided as part of, or for use in, an electronic device 118. Although identified as reference numeral 100 here, as used herein, an “apparatus” may refer to, for example, any or all of a system, device, circuitry, or a component(s) thereof, whether individually or in combination. For example, according to the present disclosure, either or both electronic device 118 and/or memory device 116 may also be considered an “apparatus.”

Electronic device 118 may represent any electronic device or portion thereof that may access memory device 116, e.g., to transfer one or more electrical signals representing some form of information (e.g., encoded as bits, data, values, elements, symbols, characters, terms, numbers, numerals, or the like). For example, electronic device 118 may comprise a computer, a communication device, a machine, etc., in which memory device 116 may be accessed by a circuit device 150, e.g., via an interface 140. Circuit device 150 may represent any circuitry that may be coupled to memory device 116. Thus, circuit device 150 may comprise some form of a processing circuit (e.g., microprocessor, microcontroller, etc.), some form of a communication circuit (e.g., a receiver, a transmitter, a bus interface, etc.), some form of coding circuit (e.g., an analog to digital converter, a digital to analog converter, an inertial sensor, a camera, a microphone, a display device, etc.), another memory device (e.g., a nonvolatile memory, a storage medium, etc.), and/or a combination thereof, just to name a few examples.

In certain example instances, memory device 116 may be provided as a separate component (e.g., chip, semiconductor die, etc.) which may be coupled to circuit device 150. In certain other instances, a memory device 116 may be provided along with one or more other circuit devices, for example, as part of a multiple chip package, a “managed” memory device, a module, a memory card, one or more semiconductor dies, and/or a system on a chip, just to name a few.

As shown, memory device 116 may, for example, comprise a plurality of memory cells 102-1 through 102-z. For the sake of brevity, in this description, the terms “memory cell 102” or “memory cells 102” may be used as a generic reference to one or more of the plurality of memory cells 102-1 through 102-z (where “z” represents a whole number).

A memory cell 102 may, for example, be selectively programmed in a state representing some form of information, such as, e.g., a binary logic bit (e.g., a “1” or a “0”). In certain example implementations, a memory cell 102 may be capable of being selectively programmed in three or more states, which may represent 1.5 bits, or two or more binary logic bits.

In this example, memory cells 102-1 through 102-z are arranged as part of an array of memory cells 114. In certain example implementations, an array of memory cells 114 may be arranged according to a pattern, such as a connecting grid of digit line (e.g., bit line) conductors and word line conductors. In certain example implementations, an array of memory cells 114 may comprise a stack (e.g., a multiple layered arrangement) of memory cells 102. In certain example implementations, a memory cell 102 may be accessed via an applicable access line, such as a bit line (BL) conductor 106, a word line (WL) conductor 108, and a return line (RL) conductor 109, e.g., using one or more of interface 140, selection circuit 126, access circuit 128, sense circuit 130, and/or the like or some combination thereof. As is known in the art, such circuitry can comprise digit line and word line driver circuits configured for applying potentials as described herein.

While the phrases “bit line” and “word line” are used herein, it should be understood that such features are not necessarily intended to be limited to any particular “bit” or “word” arrangement as may be employed in a particular electronic device. Thus, for example, in a more generic sense a “bit line” or a “word line” may simply refer to a “row line” or “column line”, or vice versa. Both the digit lines (e.g., bit lines) and word lines can be referred to more generally as “access lines.”

A memory cell 102-1 may, for example, comprise, at least in part, a memory storage component (e.g., represented here by way of example as a PCM component 110) and a selector in the form of a thyristor 112. By way of a non-limiting example, as illustrated in FIG. 1, in certain implementations a PCM component 110 may comprise an OMS. The PCM component may comprise, for example, a PCM material, such as a chalcogenide material, e.g., germanium-antimony-tellurium (GST), capable of adopting states with different resistivities in response to electrical signals. For example, GST may adopt a relatively low resistance in response to a current signal that can generate heat (e.g., through a heater in thermal communication with the GST, or through self-heating of the GST itself) by adopting a more crystalline state than prior to the signal. Conversely, a different electrical signal (e.g., generating higher current flow) can at least partially melt or amorphize GST to adopt higher resistance than prior to the signal.

As illustrated in FIG. 1, PCM component 110 may be coupled in series with thyristor 112 and comprise a first node 120 and a second node 121. As shown, first node 120 may, for example, be coupled to BL conductor 106, and second node 121 may, for example, be coupled to a first node 123 of thyristor 112. A second node 122 of thyristor 112 may, for example, be coupled to WL conductor 108, and a third node 124 of thyristor 112 may, for example, be coupled to RL conductor 109. While some of the description that follows is directed towards an example array 114 of memory cells and/or memory cell 102-1 as illustrated in FIG. 1, it should be kept in mind that other arrangements may also be implemented, e.g., as illustrated in FIGS. 9-11 and subsequently described herein.

Interface 140 may, for example, be representative of circuitry that allows for access to a memory cell 102. For example, interface 140 may provide for selective reading of one or more memory cells, e.g., in support of a READ operation. For example, interface 140 may provide for selective programming of one or more memory cells, e.g., in support of a WRITE operation (also referred to herein as a programming operation). Thus, for example, in certain implementations, interface 140 may receive one or more commands 144 and in response apply a selected operational potential to a memory cell. In certain example implementations, interface 140 may comprise all or part of the circuitry illustrated in FIG. 1 as selection circuit 126, access circuit 128, and/or sense circuit 130.

In accordance with certain example implementations, a selection circuit 126 may be provided in memory device 116 to select one or more memory cells for access. As described in greater detail herein, selection circuit 126 may, for example, select a particular memory cell for access by initiating the application of a triggering potential to affect a gate of the thyristor 112 within the memory cell 102. Thyristor 112 may comprise, for example, a three-node silicon controlled rectifier (SCR). For example, in certain implementations a triggering potential may be applied to second node 122 via WL conductor 108 to place thyristor 112 in a conductive state wherein first node 123 and third node 124 are operatively (e.g., electrically) coupled via thyristor 112. Conversely, with thyristor 112 in a “non-conductive” state, first node 123 and third node 124 are operatively (e.g., substantially electrically) isolated by thyristor 112. Although the term “non-conductive” is used herein to describe a state of a thyristor, it should be understood that in certain implementations there may be some low levels of current (e.g., leakage, etc.) that may flow from time to time through all or part of a thyristor that is in a non-conductive state.

With thyristor 112 in a conductive state, memory cell 102-1 may be considered as “selected” or “turned ON” and may be accessed, e.g., as part of a READ and/or WRITE operation. In certain example implementations, selection circuit 126 may apply a triggering potential continuously during a desired period of access. In certain other example implementations, selection circuit 126 may apply a triggering potential during a portion of a desired period of access. For example, in certain implementations a triggering potential may take the form of a signal pulse that momentarily affects a gate of thyristor 112 such that thyristor 112 may be placed in a conductive state in the presence of a selected operational potential between the first node 123 and third node 124 of the thyristor 112. This type of example trigger-based “latch-up” process is described in greater detail below with regard to FIGS. 2-4.

Selection circuit 126 may also selectively isolate memory cells that are not selected. For example, when a memory cell is not selected, selection circuit 126 may couple (external to the thyristor) the gate (second node 122) of the thyristor, which is connected to WL 108, to RL conductor 109 and/or another node that is at a potential which is less than the triggering potential, which encompasses the possibility of a reversed polarity. For example, in certain implementations RL conductor 109 may be maintained at a return potential, e.g., a ground potential (e.g., 0 volts) or some other desired potential that may be less than a triggering potential (e.g., which may be 1 volt). Selection circuit 126 may further remove or reduce a potential and/or corresponding current between the first and third nodes 123, 124 of a thyristor in a memory cell that is not selected, e.g., by altering the potential or otherwise affecting current delivered via BL conductor 106. For example, in certain implementations BL conductor 106 may be coupled (external to the thyristor) to RL conductor 109 or some applicable node to alter the potential and/or current applied to the non-selected memory cell.

Once a memory cell has been selected, access circuit 128 may apply a selected operational potential to the memory cell, e.g., between first node 120 of PCM component 110 and third node 124 of thyristor 112. Thus, for example, in FIG. 1, a selected operational potential may be provided between BL conductor 106 and RL conductor 109, and current corresponding to the selected operational potential may flow between first node 120 and second node 121 of PCM component 110 and between first node 123 and third node 124 of thyristor 112 with thyristor 112 in a conductive state. The selected operational potential may vary depending, at least in part, on a desired operation to be performed with the memory cell. For example, selected operational potentials may be different depending on whether a READ or a WRITE operation is being performed. Furthermore, as known in the art, in certain instances a selected operational potential may vary at times during a READ or a WRITE operation of a PCM component.

As part of certain example READ or WRITE operations, a sense circuit 130 may be used in memory device 116 to determine a state of a memory cell 102-1. Thus, for example, sense circuit 130 may be responsive a voltage drop and/or a current through a selected PCM component (e.g., to determine a resistance, an impedance, etc.). In certain implementations, sense circuit 130 may be responsive to a snapback event or the like, which may occur in a PCM component 110 under certain conditions and detected. For example, a snapback event may result in a sudden “negative resistance” under certain conditions. While a physical origin of a snapback event may not be completely understood, an occurrence of a snapback event tends to significantly affect a current-voltage behavior of a memory cell. As such, a sense circuit 130 may, for example, be provided which is responsive to a snapback event occurrence in a memory cell 102 to generate one or more feedback signals that initiate a change in an electric potential being applied to memory cell 102. By way of example, one or more feedback signals may initiate a change in a selected operational potential to reduce the electric potential, disconnect the electric potential, stop the generation of the electric potential, etc. For example, in certain instances, in response to determining that a snapback event has occurred in a memory cell 102, one or more feedback signals from sense circuit 130 may initiate a change in access circuit 128. The information state of the memory storage component represented by PCM component 110, when thyristor 112 is placed in a conductive state, can be communicated to sense circuit 130 by way of the digit line, referred to herein as BL conductor 106.

Attention is drawn next to FIG. 2, which is a graph 200 illustrating some example characteristics of an example thyristor circuit 112′ as illustrated in FIG. 3 and/or thyristor circuit 112″ or 112′″ as illustrated in FIGS. 4A and 4B, according to certain implementations.

FIG. 3 is a schematic diagram showing a circuit 300 comprising an example thyristor 112′ having an anode (A), a floating node (F), a gate (G), and a cathode (K) that may be used in the memory device of FIG. 1, according to an implementation. As illustrated in this example, in certain implementations the anode (A) may be coupled to PCM component 110 and cathode (K) may be coupled to a RL conductor 109 (FIG. 1), which may be at ground. The gate (G) may be coupled to a WL conductor 108 (FIG. 1).

FIG. 4A is a schematic diagram showing an example circuit 400 illustrating thyristor 112″ using a representative vertically formed stack showing a PNPN layered or regioned semiconductor configuration that may be fabricated for use in the memory device of FIG. 1, according to an implementation. Thyristor 112″ also comprises an anode (A), a floating node (F), a gate (G), and a cathode (K). Additionally, thyristor 112″ illustrates three junctions, the first of which is labeled J_{PN1} and appears where the P layer of the anode meets the N layer of the floating node, the second of which is labeled J_{NP} and appears where the N layer of the floating node meets the P layer of the gate, and the third of which is labeled J_{PN2} and appears where the P layer of the gate meets the N layer of the cathode. As illustrated in this example, in certain implementations the anode (A) may be coupled to PCM component 110, the gate (G) may be coupled to a WL conductor 108 (FIG. 1) and cathode (K) may be coupled to a RL conductor 109 (FIG. 1), which may be at ground. In this example, the gate may be affected by a triggering potential applied via a direct, e.g., ohmic contact connection. Accordingly, thyristor 112″ may take the form of a 3-node silicon controlled rectifier (SCR), or the like.

FIG. 4B is a schematic diagram showing an example circuit 420 illustrating yet another example thyristor 112′″ using a representative vertically formed stack showing a PNPN layered or regioned semiconductor configuration similar to that in FIG. 4A, but which also comprises a gate dielectric portion 422 that allows the gate to be affected by a triggering potential from, e.g., WL conductor 108 (FIG. 1), applied via a capacitive coupling. Accordingly, thyristor 112′″ may take a form of a Thin Capacitively Coupled Thyristor (TCCT), and/or the like.

FIG. 2 depicts a current-voltage (IV) characteristic for an example thyristor, according to an implementation. With reference to FIG. 2, in graph 200, the horizontal axis depicts an increasing positive voltage V_{AK} between the anode (A) and the cathode (K), and the vertical axis depicts an increasing positive current level I_{AK} flowing between the anode (A) and the cathode (K). Thyristors 112/112′/112″/112′″ may be placed in a conductive state and a non-conductive state. Here, for example, a thyristor maybe in a conductive state corresponding to the labeled “ON resistance” region of graph 200, e.g., wherein there is less resistance provided by the thyristor.

As previously mentioned, in certain example implementations in response to a triggering potential being applied to affect the gate (G), thyristors 112/112′/112″/112′″ may be selectively allowed to be placed in a conducting state in response to a concurrent application of a potential V_{AK} between an anode (A) and a cathode (K) exceeding a threshold voltage, and/or a current I_{AK} associated with the potential applied between the anode and the cathode exceeding a threshold amperage.

In the non-conductive state, e.g., where no significant current I_{AK} is expected to flow, a voltage drop up to a threshold may be sustained by a reversed bias junction J_{NP}. While in the non-conductive state, the current I_{AK} may be considered a leaking current, and the current I_{AK} will remain lower than a latching current I_{L}. The non-conductive state may be maintained until V_{AK} exceeds a threshold voltage (e.g., a break-over voltage V_{BO}). If a current is applied to the gate terminal of the thyristor 112, the threshold voltage may be lowered below the break-over voltage V_{BO}, although the thyristor 112 can be transitioned into a conductive state without such a gate current. For example, a non-conductive state may be maintained until V_{AK} exceeds a threshold voltage (e.g., a break-over voltage V_{BO}), at which point thyristors 112/112′/112″/112′″ may be placed in a conducting state. Similarly, for example, a non-conductive state may be maintained if the current I_{AK} remains lower than the latching current I_{L}.

In graph 200, lines 202, 204 and 206 represent different example levels for a current (I_{G}) at the gate which may affect the break-over voltage V_{BO} and as such the point at which thyristors 112/112′/112″/112′″ switch to/from a conductive state. For example, line 202 may represent a response to a significantly high gate current I_{G}, line 204 may represent a response to a relatively lower gate current I_{G}, and line 206 may represent a response to a very low or possibly non-existent gate current I_{G}. With thyristors 112/112′/112″/112′″ in a conductive state and provided adequate current flowing between the anode and cathode, the thyristor may remain self-biased and need not be further affected by application of a triggering potential. Here, for example, the thyristor essentially behaves as a diode with a series resistance in the conductive state. As such, a triggering potential may be momentarily applied in the form of a pulse to affect the gate in certain implementations.

A subsequent switch from a conductive state to a non-conductive state may occur, for example, in response to V_{AK} falling below a threshold voltage (e.g., a holding voltage V_{H}) and/or the current I_{AK} falling below a threshold amperage (e.g., a holding current I_{H}). It should be kept in mind that the example characteristics (e.g., V_{BO} versus I_{G}, I_{L}, V_{H}, I_{H}, and ON resistance) related to the thyristor functionality may, for example, be tuned based at least in part on the doping profile of the device, and/or other like physical properties. Accordingly, as with all of the other examples herein, claimed subject matter is not intended to be limited to these illustrated examples.

In certain instances, a thyristor may be placed in a conductive state in response to a concurrent (e.g., at least partially overlapping in time) application of an adequate potential between the anode and the cathode, and a triggering potential to affect the gate. In certain example implementations, a triggering potential may comprise a signal pulse. Thus, for example, a pulse for such a triggering potential may overlap with application of a potential applied between the anode and the cathode. A triggering potential affecting the gate may, for example, be removed or reduced (e.g., possibly leaving the gate not driven) after the thyristor reaches a conductive state, and the conductive state maintained in the presence of an adequate potential and/or current applied between the anode and cathode.

Attention is drawn next to FIG. 5, which is a diagram of an example method 500 that may be used in the memory device of FIG. 1 to select and access one or more memory cells, according to an implementation. Method 500 may, for example, be implemented, at least in part, in various apparatuses, e.g., using various circuits, circuit components, etc.

At example block 502, application of a triggering potential to affect a gate of a thyristor that is coupled in series with a memory storage component (e.g., PCM component) within an array of memory cells may be initiated to selectively allow the thyristor to be placed in a conductive state. In certain instances, at example block 504, application of a triggering potential to affect a gate of the thyristor may be initiated as part of a READ operation or a WRITE operation associated with the memory cell. In certain instances, at example block 506, a triggering potential may comprise a signal pulse applied by way of a word line, e.g., WL conductor 108 of FIG. 1.

At example block 508, application of a selected operational potential to the bit line conductor may be initiated, e.g., as part of a READ operation or a WRITE operation associated with the memory cell. For example, the potential can be applied to BL conductor 106 of FIG. 1. In certain instances, at example block 510, the conductive state may be maintained following a triggering potential (e.g., signal pulse) being removed or reduced in the presence of an adequate potential applied or corresponding current flowing between the anode and the cathode (e.g., exceeding a threshold voltage and/or a threshold amperage). Thus, method 500 may activate the thyristor selector by way of initiating signals for READ or WRITE operations. In a READ operation, for example, while the thyristor is in the conductive state, an information state of the storage component of the memory cell can be retrieved by the sense circuit (see FIG. 1). In a WRITE operation, while the thyristor is the conductive state, an information state can be programmed to the storage component of the memory cell.

FIG. 6 is a diagram of another example method 600 that may be used in the memory device of FIG. 1 to select and access one or more memory cells, according to an implementation. Method 600 may, for example, be implemented, at least in part, in various apparatuses, e.g., using various circuits, circuit components, etc., such as those shown in FIG. 1.

At example block 602, a bit line conductor (e.g., BL conductor 106 of FIG. 1) may be selectively allowed to be coupled (e.g., electrically connected) in a memory array to a return line conductor (e.g., RL conductor 109 of FIG. 1) via a memory cell having a PCM component (e.g., PCM component 110) coupled in series with a thyristor (e.g., thyristor 112), by selectively applying a triggering potential to affect a gate of the thyristor to place the thyristor in a conductive state. Block 602 may thus be equivalent to method 500 of FIG. 5 for switching the thyristor from a non-conductive to a conductive state.

At example block 604, with the bit line conductor being selectively coupled to the return line conductor via the memory storage component and thyristor, at least one of a READ operation or a WRITE operation may be performed, e.g., by applying a selected operation potential to the bit line conductor. Thus, READ and/or WRITE operations at block 604 may be conducted subsequent to activation of the thyristor selector at block 602.

At example block 606, the triggering potential may be selectively removed or reduced, which may be prior to, simultaneous with or subsequent to READ/WRITE operations at block 604. At example block 608, a floating node within the thyristor may be used to maintain the conductive state in response to the selected operational potential V_{AK} (e.g., between BL conductor 106 and RL conductor 124) exceeding a threshold voltage, or a corresponding current I_{AK} through the cell exceeding a threshold amperage. At example block 608, once the thyristor is placed in the conductive state (e.g., based on concurrent application of the triggering potential and an adequate potential and/or current applied between the anode and cathode), the thyristor may remain in the conductive state in the continued presence of the adequate potential and/or current applied between the anode and cathode.

FIG. 7 is a diagram of an example method 700 that may be used in the memory device of FIG. 1 to selectively isolate one or more memory cells, according to an implementation. Method 700 may, for example, be implemented, at least in part, in various apparatuses, e.g., using various circuits, circuit components, etc., such as those shown in FIG. 1.

At example block 702, a potential affecting a gate of the thyristor may be removed or reduced to less than a triggering potential. In certain instances, for example at block 704, if the gate is coupled to a word line conductor, to remove or reduce the triggering signal the word line conductor may be coupled to a return potential, e.g., ground.

At example block 706, a potential between an anode and a cathode of the thyristor may be removed or reduced to less than an operational potential or threshold potential, and/or a corresponding current may be reduced to less than a threshold amperage. In certain instances, for example, at block 708, if the anode is coupled to a bit line conductor, the potential may be removed or reduced by coupling the bit line conductor to a return potential, e.g., ground.

Attention is drawn next to FIG. 8, which is an example state diagram 800 for use in controlling a memory cell that may be selected and turned ON for access and/or turned OFF for isolation, according to an implementation. Example state diagram 800 and/or all or part of the actions shown therein may, for example, be implemented, at least in part, in various apparatuses, e.g., using various circuits, circuit components, etc., such as those shown in FIG. 1.

In state 802, the memory cell may be OFF, e.g., as a result of the thyristor that is coupled in series with a memory storage component (e.g., a PCM component) being in a non-conductive state. Further, in certain implementations, at action 810, a memory cell may be maintained in an isolated condition by coupling (external to the thyristor) an anode and/or a gate in the thyristor to a cathode, e.g., which may be at a return potential. For example, with reference to FIG. 1, BL conductor 106, WL conductor 108 and RL conductor 109 can be all connected to the same potential, e.g., ground.

At action 812, a trigger potential may be applied to a gate of the thyristor to selectively allow the thyristor to be placed in a conducting state, which selects the memory cell and places it in memory cell ON state 804. In certain instances, a trigger potential may comprise a signal pulse etc. It will be understood that the trigger potential (e.g., WL pulse) need only overlap with application of the anode-cathode (e.g., BL-RL) threshold voltage or current.

At action 814, a selected operational potential and/or corresponding current may be maintained above their respective threshold levels to keep the thyristor in a conducting state and hence the memory cell in memory cell ON state 804. As will be clear from the foregoing description, the triggering potential from action 812 need not be maintained in order to maintain the ON state 804. Further, at action 816, while the memory cell is in an ON state, one or more READ operations and/or one or more WRITE operations, or some combination thereof and/or the like may be performed.

At action 818, the thyristor may be placed in a nonconducting state by removing or reducing the selected operational potential and/or corresponding current to level(s) below their respective threshold levels that were used to keep the thyristor in a conducting state. Consequently, the memory cell may be placed in memory cell OFF state 802. For example, with reference to FIG. 1, BL conductor 106 and RL conductor 109 can be both connected to the same potential, e.g., ground. Because the trigger potential to the thyristor gate by way of WL conductor 108 at action 812 can be a transitory pulse, the WL conductor 108 may already be connected to the return potential, e.g., ground.

Attention is drawn next to FIGS. 9-11, which are schematic diagrams showing example apparatuses (partial circuits) having example memory cells that may be used in the memory device of FIG. 1 and which comprise a memory cell storage component in the form of a PCM component, and a memory cell selector in the form of a thyristor arranged according to certain alternative implementations.

In FIG. 9, an example circuit 900 comprises a memory cell 902 that is similar to memory cell 102-1 in FIG. 1, but differs in that a BL conductor is coupled to the gate of thyristor 112 and a WL conductor is coupled to the first node of PCM component 110.

In FIG. 10, an example circuit 1000 comprises a memory cell 1002 that is similar to memory cell 102-1 in FIG. 1, but differs in that thyristor 112 and PCM component 110 are arranged in a reversed order wherein a BL conductor is coupled to the anode of thyristor 112, a WL conductor is coupled to the gate of thyristor 112, the cathode of thyristor 112 is coupled to the first node of PCM component 110, and the second node of PCM component 110 is coupled to a RL conductor.

In FIG. 11, an example circuit 1100 comprises a memory cell 1102 that is similar to memory cell 1002 in FIG. 10, but differs in that a WL conductor is coupled to the anode of thyristor 112, and a BL conductor is coupled to the gate of thyristor 112.

In accordance with certain aspects, it is believed that the example implementations and underlying techniques provided herein may provide several advantages over other circuit designs that use a bipolar junction transistor (BJT) or the like as a selector. While some examples presented herein are PCM-based memory circuits, it is further believed that the techniques may also be used in other point-to-point memory arrays/circuits wherein a three node selector drives a memory cell storage component, e.g., a resistive storage component in which the current may flow unidirectionally.

The techniques provided herein may, for example, provide a benefit in that a traditional bipolar junction transistor (BJT) base current may be avoided after the thyristor is placed in a conductive state (e.g., the memory cell is ON), which may reduce or possibly eliminate unwanted WL drops during READ/WRITE operations. Here, for example, with some PCM memory designs operations that change and read the state of the memory cells may require a non-negligible amount of current that flows both into resistive bit line conductors and word line conductors in the array. The consequent voltage drop may limit a working window of the memory cell and/or the array's efficiency. A WL voltage drop may increase for various reasons, such as, e.g., the number of memory cells that are in READ/WRITE operations at the same time on a single WL conductor, the length of the WL conductor and/or the specific resistance of the WL conductor, just to name a few. Should a WL voltage drop generate non-uniform polarization for the selected cells along the WL conductor, the READ and WRITE window budget of the memory cells may be proportionally reduced, e.g., by the amount of the voltage drop.

In certain instances, it is believed that such WL voltage drops may be avoided or greatly reduced using the techniques provided herein. Accordingly, one or more of the following example improvements may be realized, and possibly without significantly affecting READ and WRITE window budgets: a greater number of simultaneous READ/WRITE operations may be performed for cells in the same WL; a longer WL and consequently possibly higher array efficiency may be achieved; and/or a higher WL resistivity may be allowed, e.g., which can be traded off to facilitate integration and/or reducing cost, etc. Indeed, as described below, the structure of the WL can be simplified in recognition of the reduced demands on conductivity for the WL.

FIG. 12 is a schematic diagram showing an example configuration of the memory cell with a metal word line conductor and a buried word line conductor. In a memory device, the WL may be composed of multiple parts. In this implementation, the memory array may include a buried WL 1220 and a metal WL 1222. The buried WL 1220 may be formed by semiconductor material, such as a doped portion of a semiconductor substrate 1230 or an epitaxial layer thereover. The metal WL 1222 may be connected to the buried WL 1220 through one or more WL contacts 1224. The WL contacts 1224 can provide an electrical connection between the buried WL 1220 and the metal WL 1222. The buried WL 1220 can be connected to a plurality of memory cells 1202. For each cell 1202, the buried WL 1220 may be connected to the gate of the thyristor selector, which is a component of the memory cell 1202. The anode of the thyristor selector may be connected to the memory storage component, which is also a component of the memory cell 1202. Each memory cell 1202 can be connected to a BL 1206. In particular, the memory storage component of the memory cell 1202 may be connected to a BL 1206. In the illustrated embodiment, the BLs 1206 extend into and out of the page and therefore cross with the WLs 1220 of the array, such that each cell can be addressed by selected a WL 1220/1222 and a bit line 1206.

A memory array using a non-thryristor selector (e.g., a BJT selector) experiences voltage drops along the WL, which can limit the number of memory cells that may be connected to the buried WL 1220 between adjacent WL contacts 1224 for connection to the lower resistivity metal WL 1222. FIG. 12, for example, depicts three memory cells 1202 connected to the buried WL 1220 between adjacent WL contacts 1224. In such an implementation, the number of memory cells 1202 that may be connected to the buried WL 1220 between adjacent WL contacts 1224 may be inversely proportional to the resistivity of the buried WL 1220, so that the higher the resistivity of the buried WL, the fewer memory cells 1202 that may be connected between adjacent WL contacts 1224. The overall resistivity of the metal WL 1222 and buried WL 1220 may limit the number of cells in the same WL that may be accessed at substantially the same time, which in turn can limit the speed or other performance of the memory.

For example, in one implementation using a BJT as a selector, a buried WL conductor (e.g., doped silicon with resistivity of about 15 mΩ·cm or a material with sheet resistance of about 1000Ω/□) can be limited to about 4-8 memory cells along one buried WL conductor between adjacent WL contacts. The constraint on the number of cells along one buried WL conductor between adjacent WL contacts may limit the efficiency of the memory array and may limit the effective memory cell dimension, increasing the required size of the memory array for a given capacity. Additional use of the strapping metal portion of the WL conductor (e.g., metal such as copper (Cu) with resistivity of about 10 μΩ·cm or a material with sheet resistance of about 1Ω/□) allows for greater numbers of cells along the WL that can be simultaneously accessed, but still results in a limit of, e.g., about 100 memory cells along the WL. In addition to requiring low resistivity materials such as copper (Cu), along with the constraints of such materials (e.g., Cu cannot currently be dry etched and calls for damascene processing), the metal WL conductor may be also be constrained as to the minimum dimensions of the line thickness or width. For example, the resistivity of copper strongly increases when the thickness or width of the conductive line is reduced below about 25 nm. This constraint on the thickness of the metal WL conductor may limit the reduction of the WL dimensions during fabrication and may limit the minimum dimension for the memory cell and the memory array.

Use of a thyristor as a selector for a memory cell can overcome resistivity limitations on the WL conductor and thus expand options available for design of the memory array and WL conductor(s). In one embodiment, using a thyristor as a selector with a WL conductor connected to the thyristor gate, a greater number of memory cells can be connected to the buried WL conductor between adjacent WL contacts, such as 10-100 cells between contacts, for example 20-50 memory cells between WL contacts. In fact, due to the polarities possible for a cross-point memory array with thyristor selectors (see below), there may be theoretically no limitation on the number of memory cells along a word line. With or without strapping metal WL 1222, greater than 125 cells, e.g. 150-500 cells can be simultaneously accessed along a single WL. In some embodiments, a higher resistivity metal can be used for the metal WL 1222, such as metals having a resistivity greater than about 15 μΩ·cm or a material with sheet resistance of greater than about 1.5Ω/□). Examples of such materials include, without limitation, tungsten (W). Use of a more resistive metal for the WL conductor may reduce limitations on the number of memory cells that may be selected substantially simultaneously. Use of a more resistive metal for the metal WL conductor may also allow manufacturing process flexibility and allow savings in product cost. Similarly, the resistivity of the buried WL 1220 can be increased relative to use of a BJT selector, such as greater than about 15 mΩ·cm, more particularly greater than about 40 mΩ·cm, or a material with sheet resistance greater than about 700Ω/□, more particularly greater than about 5000Ω/□. In another embodiment, the metal strapping layer can be omitted and the buried WL 1220 can support all of the signal along the WL.

The techniques provided herein may, for example, provide a benefit in that a NOR like array polarization/isolation scheme may be advantageously provided, e.g., wherein unselected BL conductors and WL conductors may shorted (external to the thyristor) to a return potential (e.g., ground), while selected memory cells may be polarized to a voltage greater than the return potential.

FIG. 13 is a schematic diagram showing example memory cells including a BJT as a selector configured in a two by two (2×2) array. In the diagram, memory cells 1302a, 1302b, 1302c, 1302d are configured in a point to point memory array. Each memory cell 1302a, 1302b, 1302c, 1302d includes a memory storage component, which may be a PCM storage component, and a BJT selector 1311. The positions of the storage component and selector may be reversed within the cells. One node of each memory cell 1302a and 1302c is connected to BL 1303. One node of each memory cell 1302b and 1302d is connected to BL conductor 1301. One node of each memory cell 1302a and 1302b is connected to WL conductor 1309. One node of each memory cell 1302c and 1302d is connected to WL conductor 1307. WLs 1307, 1309 can be connected to bases of BJT selectors 1311 and BLs 1301, 1303 can be connected to nodes of the memory storage components.

Voltages may be applied to the BLs 1301, 1303 and to the WLs 1307, 1309 to select (e.g. turn on/access, read, write, and/or verify) memory cells. Voltages applied to the BLs 1301, 1303 and WLs 1307, 1309 may enable access to the memory cells according to the following table, where the voltages levels are examples of levels covering reading and programming operations:

TABLE I

| | BL = 0 V | BL = 1 V-5 V |
|---|---|---|
| WL = 0 V | OFF (A′) | ON (B′) |
| WL = 1 V-5 V | OFF (C′) | OFF (D′) |

According to the table, in order to select a memory cell, a voltage may be applied to the BL connected to the memory cell to be selected and no voltage may be applied to the WL connected to the memory cell to be selected. In the diagram of FIG. 13, memory cell 1302b may be selected by applying a voltage to BL 1301 and applying no voltage to WL 1309. To ensure that memory cell 1302d remains unselected, a voltage may be applied to WL 1307. To ensure that memory cell 1302a remains unselected, no voltage may be applied to BL 1303. Accordingly, memory cell 1302c and all other unselected memory cells in the array that are not connected to BL 1301 or WL 1309, may be connected to WL 1307 or another WL where a voltage may be applied and to BL 1303 or another BL where no voltage may be applied. In an array of size N by N (N×N) that is larger than a 2×2 array, where one memory cell is selected, the number of memory cells corresponding to a selected WL (a WL that may have no applied voltage) is on the order of magnitude of N. The number of memory cells corresponding to a selected BL (a BL that may have an applied voltage) is on the order of magnitude of N. The number of memory cells corresponding to an unselected WL (a WL that may have an applied voltage) and an unselected BL (a BL that may have no applied voltage) is on the order of magnitude of N².

In the array of the diagram of FIG. 13, the program current 1320 resulting from the voltages applied to select a memory cell can flow from BL 1301, where the voltage is applied, across the memory cell 1302b and down WL 1309. The leakage current 1322 resulting from the voltages applied to maintain an unselected state for the memory cells not selected can flow from WL 1307 across memory cell 1302c and down BL 1303. The leakage current may occur in every memory cell in an array that is not connected to a selected BL 1301 or a selected WL 1309. Therefore, in a 2×2 array, the leakage may occur across one memory cell 1302c. In an N×N array, the leakage may occur across (N−1)² memory cells. As a memory array using a BJT selector increases in size, the leakage of the array may increase in proportion with the square of the number of memory cells in a row or column of the array.

FIG. 14 is a schematic diagram showing example memory cells including a thyristor as a selector configured in a two by two (2×2) array, according to an implementation. In the implementation of FIG. 14, memory cells 1402a, 1402b, 1402c, 1402d are configured in a point to point memory array. Each memory cell 1402a, 1402b, 1402c, 1402d includes a memory storage component, which may be a PCM storage component, and a thyristor selector 1412. The positions of the storage component and selector may be reversed within the cells. One node of each memory cell 1402a and 1402c may be connected to BL 1407. One node of each memory cell 1402b and 1402d may be connected to BL conductor 1409. One node of each memory cell 1402a and 1402b may be connected to WL conductor 1401. One node of each memory cell 1402c and 1402d may be connected to WL conductor 1403. Each WL 1401, 1403 may be connected to gates of thyristor selectors 1412 and each BL 1407, 1409 can be connected to nodes of the memory storage components.

Voltages may be applied to the WLs 1401, 1403 and to the BLs 1407, 1409 to select (e.g. turn on/access, or read, write, or verify) the memory cell. Voltages applied to the WLs 1401, 1403 and BLs 1407, 1409 may enable access to the memory cell according to the following table, where the voltages levels are non-limiting examples of levels covering reading and programming operations:

TABLE II

| | BL = 0 V | BL ≈ 1-5 V |
|---|---|---|
| WL = 0.5-0.7 V | OFF (A) | ON (B) |
| WL = ~0 V | OFF (C) | OFF (D) |

According to the table, in order to select a memory cell, a voltage may be applied to the BL connected to the memory cell to be selected and a voltage may be applied to the WL connected to the thyristor gate of the memory cell to be selected. Unselected WLs and unselected BLs can have no applied voltage, e.g., connected to a return or ground line. In the implementation shown in FIG. 14, memory cell 1402b may be selected by applying a voltage to WL 1401 and applying a voltage to BL 1409. To ensure that memory cell 1402d remains unselected, no voltage may be applied to WL 1403. To ensure that memory cell 1402a remains unselected, no voltage may be applied to BL 1407. Accordingly, memory cell 1402c and all other unselected memory cells in the array that are not connected to WL 1401 or BL 1409, may be connected to BL 1407 or another BL where no voltage may be applied and to WL 1403 or another WL where no voltage may be applied. In an array of size N by N (N×N) that is larger than a 2×2 array, where one memory cell is selected, the number of memory cells corresponding to a selected WL (a WL that may have an applied voltage) is on the order of magnitude of N. The number of memory cells corresponding to a selected BL (a BL that may have an applied voltage) is on the order of magnitude of N. The number of memory cells corresponding to an unselected BL (a BL that may have no applied voltage) and an unselected WL (a WL that may have no applied voltage) is on the order of magnitude of N².

In the implementation shown in FIG. 14, the program current 1420 that may result from the voltage applied to the BL 1409 to select a memory cell can flow from BL 1409, where the voltage is applied, across the memory cell 1402b and down to the cathode of thyristor 1412 of memory cell 1402b. The switch-on current 1424 that may result from the voltage applied to the WL 1401 to select a memory cell can flow from WL 1401, where the voltage is applied, to the gate of thyristor 1412 of memory cell 1402a and down to the cathode of thyristor 1412 of memory cell 1402a. The leakage current 1422 resulting from the voltage differential applied to maintain an unselected state for the memory cells not selected can flow from BL 1409 across memory cell 1402d and down WL 1403. The leakage current may occur in every memory cell in an array that is connected to a selected BL 1409. Therefore, in an 2×2 array, the leakage may occur across one memory cell 1402c. In an N×N array, the leakage may occur across N−1 memory cells. As a memory array using a thyristor selector increases in size, the leakage of the array may increase in proportion with the number of memory cells in a row or column of the array, as opposed to the square of the number of memory cells in a row or column of the array as in a BJT selector memory array.

With certain PCM technology, some scaling paths may lead to: higher voltages that the memory cell selectors may need to sustain; a higher doping of certain selector junctions; and/or a greater number of non-selected selectors that may need to be polarized in standby mode. Thus, in certain instances, such scaling may lead to a potential for an increase of leakage currents, which tend to reduce efficiency even in standby modes.

In certain instances, it is believed that the techniques provided herein may reduce or possibly avoid such inefficiencies. For example, in certain example implementations, when all of part of an array memory cells is not being accessed as part of a READ or WRITE operation, the unselected corresponding BL conductors and/or WL conductors may be coupled to a return potential (e.g., ground) which may reduce or even avoid all or part of the complications that may occur with an array being polarized (e.g., leakage, voltage balancing, etc.). Thus, for example, with the techniques provided herein, it may be possible that few if any memory cells may be polarized in standby mode (OFF state) and that, as such, little if any leakage current may as a result be sunk from supplies. Further, for example, with the techniques provided herein, it may possible that a number of leaking cells in a READ and/or WRITE operation may be proportional to a linear size of the BL conductor rather than being proportional to its squared value. In still another example, with the techniques provided herein, it may possible for BL and WL conductors to be substantially insulated (e.g., by a reversed biased diode between the gate and floating node of a thyristor) instead of having a diode that may be directly polarized there between. Another possible advantage is that a possible WL/BL short in an array may become easier to manage, e.g., in a testing flow, etc., and may possibly be repaired by specific column and row instead of through tile redundancy. Another possible benefit may be that, in certain example implementations a WL voltage (e.g., triggering potential) may range between a return potential and about 1 volt, which may allow for relatively lower voltage transistors to be used instead of a high voltage transistor (e.g., in row decoder, etc.). This potential advantage, e.g., allowing reduction of the selected WL voltage value range to between about 1 volt and above a ground potential, may result from the negligible current produced on the WL after a thyristor selector is switched on. This reduction in voltage applied to the WL may allow use of low voltage transistors as part of a row decoder. Low voltage transistors in the row decoder may allow a reduction in the size of the row decoder and increase efficiency across the memory array.

FIG. 15 is an illustration depicting an isometric view of a portion of an example memory device including bipolar junction transistors as selectors for each cell. In the illustration of FIG. 15, the BJT selector component in the memory array is formed from a semiconductor layer stack. The semiconductor layer stack may be formed on a substrate. A collector region 1510 may comprise a p-type semiconductor, for example, p-type silicon. A base region 1520 may comprise an n-type semiconductor. An emitter region 1530 may comprise a p-type semiconductor. The plane where the emitter region 1530 is in contact with the base region 1520 may form junction J₁ 1506. The plane where the base region 1520 is in contact with the collector region 1510 may form junction J₂ 1508. The semiconductor layers on the substrate, e.g., the collector region 1510, the base region 1520 and the emitter region 1530 may be formed by epitaxial deposition or by etching and doping regions of a bulk substrate or by a combination of etching and epitaxial deposition. The semiconductor layer stack may be patterned to form an array of selectors that may be used in a memory cell array. The pattern may result in individual BJT selectors separated by trenches 1502, where each selector may share one or more collector, base, or emitter regions with another BJT selector. For example, the base regions 1520 of adjacent cells can be connected, as shown, and form part of a buried WL conductor. Although not shown, the cells can include memory storage components connected in series above the emitter regions 1530 of the BJT selectors, with BL conductors connected in series above the memory storage components.

FIGS. 16A and 16B are illustrations depicting cross-sectional views of an example memory device including a BJT as a selector. FIG. 16A illustrates a cross-sectional view along the WL direction of the example memory device using a BJT as a selector. FIG. 16B illustrates another cross-sectional view along the WL direction of the example memory device using a BJT as a selector as FIG. 16A. In the illustrations of FIGS. 16A and 16B, a collector region 1510, a base region 1520, and an emitter region 1530 form part of a semiconductor stack. The junction J₁ 1506 may be between the emitter region 1530 and the base region 1520. The junction J₂ 1508 may be between the base region 1520 and the collection region 1510. The cross-sectional view of FIG. 16B can be a cross-section along a different WL illustrated in FIG. 15. Accordingly, the four BJT selector pillars shown in FIGS. 16A and 16B may form a 2×2 array where pillar B′ and pillar D′ share a BL conductor and pillar A′ and pillar C′ share a different BL conductor.

Voltages may be applied across the memory cells according to the table in FIG. 13. To access a memory cell associated with BJT selector pillar B′, a voltage may be applied along the BL conductor connected to emitter 1530 of pillar B′ and shared by pillar D″, while ground voltage is applied to the WL in communication with the base 1520 of pillar B′. The program current 1320 flows through the memory cell associated with BJT selector pillar B′. To ensure that other memory cells in the 2×2 array remain unselected, no voltage may be applied to the BL conductor shared by pillar A′ and pillar C′ while a voltage is applied to the WL conductor (base region 1520) shared by pillar C′ and pillar D′. The applied voltages may produce a reversed biased junction at junction J₂ 1508 in both pillar C′ and pillar D′. The applied voltages may also produce a reverse biased junction at junction J₁ 1506 in pillar C′. The reverse biased junctions may produce leakage currents across the memory array. In an array of size N×N that is larger than a 2×2 array, according to the illustration of FIGS. 16A and 16B where one memory cell is selected, the number of memory cells that may produce leakage current across the array is on the order of magnitude of N².

FIG. 17 is an illustration depicting isometric view of a portion of an example memory device including thyristors as selectors for each cell, according to an implementation. In the implementation of FIG. 17, the thyristor selector component in the memory array is formed from a semiconductor layer stack. The semiconductor layer stack may be formed on a substrate. A cathode region 1710 may comprise an n-type semiconductor, for example, n-type silicon. A gate region 1720 may comprise a p-type semiconductor. A floating region 1730 may comprise an n-type semiconductor. An anode region 1740 may comprise a p-type semiconductor. The plane where the anode region 1740 is in contact with the floating region 1730 may form junction J_{PN1} 1704. The plane where the floating region 1730 is in contact with the gate region 1720 may form junction J_{NP} 1706. The plane where the gate region 1720 is in contact with the cathode region 1710 may form junction J_{PN2} 1708. The semiconductor layers on the substrate, e.g., the cathode region 1710, the gate region 1720, the floating region 1730, and the anode region 1740 may be formed by epitaxial deposition, doping and etching regions of a bulk substrate, or a combination of doping/etching bulk semiconductor and epitaxial deposition.

The semiconductor layer stack may be patterned to form an array of selectors that may be used in a memory cell array. The pattern may result in individual thyristor selectors separated by trenches 1702 that may share one or more cathode, gate, floating, or anode regions with another thyristor selector. For example, the cathode region 1710 can be a blanket layer shared across cells at the junctures of multiple columns and rows (BLs and WLs, respectively) across the array, such as across the entire array; and gate regions 1720 of adjacent cells can be connected, as shown, in a continuous semiconductor line which is connected to, and forms part of, WL conductor. At each pillar thyristor, the semiconductor line forms gate nodes for the thyristors. Pillar A and pillar B are shown to share one WL conductor, connected to a common gate region 1720 for the two thyristor selectors, while pillar C and pillar D share another WL conductor, connected to a common gate region 1720 for those two thyristor selectors. Although not shown, the cells can include memory storage components connected in series above the anode regions 1740 selectors, with BL conductors connected in series above the memory storage components. The trenches 1702 that separate the pillars include a first plurality of trenches 1702 extending in the WL direction, formed through an anode layer (forming anode regions 1740), floating layer (forming floating regions 1730), gate layer (forming gate regions 1720), and partly into the cathode layer (forming a continuous cathode region 1710 across the array). The trenches 1702 also include a second plurality of trenches extending in the BL direction, formed through the anode layer and the floating layer and formed partly through the gate layer to define a buried gate line connecting a row of memory cells.

FIGS. 18A and 18B are illustrations depicting cross-sectional views of an example memory device including a thyristor as a selector, according to an implementation. In the implementation of FIGS. 18A and 18B, FIG. 18A illustrates a cross-sectional view along the WL direction of the example memory device using thyristors as a selectors. FIG. 18B illustrates a cross-sectional view along another WL conductor of the array. In the implementation of FIGS. 18A and 18B, the cathode region 1710, the gate region 1720, the floating region 1730, and the anode region 1740 form part of a semiconductor stack. The junction J_{PN1} 1704 may be between the anode region 1740 and the floating region 1730. The junction J_{NP} 1706 may be between the floating region 1730 and the gate region 1720. The junction J_{PN2} 1708 may be between the gate region 1720 and the cathode region 1710. Accordingly, the four thyristor selector pillars shown in the implementation of FIGS. 18A and 18B may form a 2×2 array where pillar B and pillar D share a BL conductor and pillar A and pillar C share a different BL conductor. Pillar B and pillar A share a WL conductor electrically connected to the common gate region 1720. Pillar C and pillar D share a different WL conductor electrically connected to their common gate region 1720.

Voltages may be applied across the memory cells according to Table II and FIG. 14. To access a memory cell associated with thyristor selector pillar B, a voltage may be applied to the BL in communication with the anode region 1740 of pillar B, such as through an intervening memory storage component (indicated in FIG. 18A as BL voltage input at node 1802b). A voltage may also be applied at WL input 1810, representing a WL contact to the common gate region 1720. The WL input can be applied simultaneously with the BL voltage input to node 1802b or as a transitory signal pulse that turns the thyristor selector pillar B on. The program current 1420 flows through the memory cell associated with thyristor selector pillar B to the cathode region 1710. To ensure that other memory cells in the 2×2 array remain unselected, no voltage input may be applied to node 1802a of pillar A, representing the BL conductor associated with pillars A and C. Pillar B and pillar D may receive an input from the same applied voltage from their shared BL conductor, which may result in an applied voltage input to node 1802d of pillar D. To ensure that the memory cell associated with thyristor selector pillar D may not be accessed, ground voltage may be applied at WL input 1808 since the floating region N 1730 already isolates the anode 1740 and gate 1720. Pillar C may receive no voltage input to the node 1802c of pillar C and no applied voltage at WL input 1808. The applied voltages across the 2×2 array may produce a reversed biased junction at junction J_{NP} 1706 in pillar D. The applied voltages may also produce a reverse biased junction at junction J_{PN1} 1704 in pillar A and a direct biased junction at junctions J_{NP} 1706 in pillar A and J_{PN2} 1708 in row 1810. These biased junctions may produce leakage currents across the memory array only along selected BLs and WLs, as explained above. In an array of size N×N that is larger than a 2×2 array, according to the implementation of FIGS. 18A and 18B where one memory cell is selected, the number of memory cells that may produce leakage current across the array is on the order of magnitude of N (e.g., about 2×N).

In the example implementations of FIG. 14 and FIGS. 18A and 18B, the use of the thyristor as a selector may translate the access method of a point-to-point array into a NOR-like array, e.g, unselected WLs and BLs may be held to a ground potential and selected WLs and BLs may be polarized to a voltage greater than a ground potential. As indicated by the example of Table II above, in an array of thyristor-selected memory cells to read or write a bit, the selected BL may be biased relatively high, and the selected WL may be slightly biased positively. The example implementations of FIG. 14 and FIGS. 18A and 18B may further include one or more reverse biased diode(s). The reverse biased diode(s) at the floating regions of unselected memory cells may be configured to insulate between one or more WLs and one or more BLs. A NOR-like array polarization scheme may be more robust as to leakage than a point-to-point array, and preferably where the WLs and BLs may be insulated by one or more reverse biased diodes. In addition, where unselected WLs and BLs may be held to a ground potential, voltage balance complications across the memory array may be reduced.

Further still, as illustrated by a comparison of FIGS. 15-16B with the embodiments of FIGS. 4A and 4B and in FIGS. 17-18B, in certain instances a thyristor device may be fabricated in an extension of techniques that may be currently in use for provisioning vertical BJT selectors, e.g., such as a double crossed shallow trench insulation in certain current PCM processes. Here, for example, a p-n-p junction process used to provide a BJT may be extended to include a further p-n junction, e.g., added as a lower layer to provide a vertical p-n-p-n structure. Here, for example, in certain instances, an upper p-doped region may be connected to an upper part of the cell, e.g., an anode of the thyristor. An upper n-doped region may not be connected to external nodes and hence it may form the floating node. A lower p-doped region may be connected to the gate of the thyristor. A “new” lower n-doped region may, in certain instances, serve as the bulk of the array, e.g., and may be used in connecting the cathode(s) of the applicable thyristor(s).

In certain example implementations, all or part of a return line may provide a low impedance path from the cathode to the reference (ground) voltage, for instance by a highly doped n+ layer, by local shorting to an underlying substrate, or by a combination of the above techniques.

Although certain example implementations have been illustrated herein by way of example, it should be kept in mind that other equivalent implementations may be provided. For example, in certain instances a gate of a thyristor, e.g., an SCR, may be placed in an N-type middle layer leaving a P-type floating node. Similarly, in certain instances, an anode and a cathode may be reversed (e.g., reversing both the current direction and the polarization scheme). In yet other instances, internal nodes (e.g., n-type and/or p-type) of a thyristor may could be coupled to (or otherwise affected by) separate word lines or the like.

The terms, “and”, “or”, and “and/or” as used herein may include a variety of meanings that also are expected to depend at least in part upon the context in which such terms are used. Typically, “or” if used to associate a list, such as A, B or C, is intended to mean A, B, and C, here used in the inclusive sense, as well as A, B or C, here used in the exclusive sense. In addition, the term “one or more” as used herein may be used to describe any feature, structure, or characteristic in the singular or may be used to describe a plurality or some other combination of features, structures or characteristics. Though, it should be noted that this is merely an illustrative example and claimed subject matter is not limited to this example.

Methodologies described herein may be implemented by various mechanisms depending, at least in part, on applications according to particular features or examples. For example, methodologies may be implemented in hardware, firmware, or combinations thereof, along with software. In a hardware implementation, for example, a processing unit may be implemented within one or more application specific integrated circuits (ASICs), digital signal processors (DSPs), digital signal processing devices (DSPDs), programmable logic devices (PLDs), field programmable gate arrays (FPGAs), processors, controllers, micro-controllers, microprocessors, electronic devices, other devices units designed to perform functions described herein, analog circuitry, or combinations thereof.

In the preceding detailed description, numerous specific details have been set forth to provide a thorough understanding of claimed subject matter. However, it will be understood by those skilled in the art that claimed subject matter may be practiced without these specific details. In other instances, methods or apparatuses that would be known by one of ordinary skill have not been described in detail so as not to obscure claimed subject matter.

Some portions of the preceding detailed description have been presented in terms of logic, algorithms or symbolic representations of operations on binary states stored within a memory of a specific apparatus, such as a special purpose computing device or platform. In the context of this particular specification, the term specific apparatus or the like includes a general purpose computer once it is programmed to perform particular functions pursuant to instructions from program software. Algorithmic descriptions or symbolic representations are examples of techniques used by those of ordinary skill in the signal processing or related arts to convey the substance of their work to others skilled in the art. An algorithm is here, and generally, is considered to be a self-consistent sequence of operations or similar signal processing leading to a desired result. In this context, operations or processing involve physical manipulation of physical quantities. Typically, although not necessarily, such quantities may take the form of electrical or magnetic signals capable of being stored, transferred, combined, compared or otherwise manipulated as electronic signals representing information. It has proven convenient at times, principally for reasons of common usage, to refer to such signals as bits, data, values, elements, symbols, characters, terms, numbers, numerals, information, or the like. It should be understood, however, that all of these or similar terms are to be associated with appropriate physical quantities and are merely convenient labels. Unless specifically stated otherwise, as apparent from the following discussion, it is appreciated that throughout this specification discussions utilizing terms such as “processing,” “computing,” “calculating,” “determining,” “establishing”, “obtaining”, “identifying”, “selecting”, “generating”, or the like may refer to actions or processes of a specific apparatus, such as a special purpose computer or a similar special purpose electronic computing device. In the context of this specification, therefore, a special purpose computer or a similar special purpose electronic computing device is capable of manipulating or transforming signals, typically represented as physical electronic or magnetic quantities within memories, registers, or other information storage devices, transmission devices, or display devices of the special purpose computer or similar special purpose electronic computing device. In the context of this particular patent application, the term “specific apparatus” may include a general purpose computer once it is programmed to perform particular functions pursuant to instructions from program software.

In some circumstances, operation of a memory device, such as a change in state from a binary one to a binary zero or vice-versa, for example, may comprise a transformation, such as a physical transformation. With particular types of memory devices, a physical transformation may comprise a physical transformation of an article to a different state or thing. For example, but without limitation, for some types of memory devices, a change in state may involve an accumulation or storage of charge or a release of stored charge. Likewise, in other memory devices, a change of state may comprise a physical change or transformation in magnetic orientation or a physical change or transformation in molecular structure, such as from crystalline to amorphous or vice-versa. In still other memory devices, a change in physical state may involve quantum mechanical phenomena, such as, superposition, entanglement, or the like, which may involve quantum bits (qubits), for example. The foregoing is not intended to be an exhaustive list of all examples in which a change in state for a binary one to a binary zero or vice-versa in a memory device may comprise a transformation, such as a physical transformation. Rather, the foregoing are intended as illustrative examples.

A computer-readable (storage) medium typically may be non-transitory or comprise a non-transitory device. In this context, a non-transitory storage medium may include a device that is tangible, meaning that the device has a concrete physical form, although the device may change its physical state. Thus, for example, non-transitory refers to a device remaining tangible despite a change in state. A computer-readable (storage) medium may, for example, be provided for use with an electronic device 118, or with other circuitry of apparatus 100 (FIG. 1).

While there has been illustrated or described what are presently considered to be example features, it will be understood by those skilled in the art that various other modifications may be made, or equivalents may be substituted, without departing from claimed subject matter. Additionally, many modifications may be made to adapt a particular situation to teachings of claimed subject matter without departing from central concept(s) described herein.

Therefore, it is intended that claimed subject matter not be limited to particular examples disclosed, but that claimed subject matter may also include all aspects falling within the possibility of appended claims, or equivalents thereof.

We claim:

1. A memory device, comprising:
a plurality of digit line conductors;
a plurality of word line conductors;
an array of memory cells at the junctures of the digit line conductors and the word line conductors, each memory cell comprising a selector thyristor and a memory storage component;
a first node of each memory storage component coupled to one of the digit line conductors;
a second node of each memory storage component coupled to an anode of the corresponding selector thyristor;
a gate of each selector thyristor coupled to one of the word line conductors; and
a cathode of each selector thyristor connected to a common return line.

2. The memory device as recited in claim 1, wherein the each word line conductor includes a semiconductor line, wherein the semiconductor line forms the gate nodes of a plurality of the selector thyristors.

3. The memory device as recited in claim 2, wherein the cathode of each selector thyristor forms part of a common semiconductor layer across the array.

4. The memory device as recited in claim 1, comprising circuitry configured to apply a first potential between one of the digit line conductors and the cathode of the selector thyristor of a selected memory cell, wherein a second potential is applied between the gate and the cathode of the selector thyristor, and wherein the selector thyristor is configured to be in a conductive state in response to at least one of:
a resulting potential across the anode and the cathode of the selector thyristor of the selected memory cell exceeding a threshold voltage; and
a current associated with the resulting potential exceeding a threshold current.

5. The memory device as recited in claim 4, wherein the selector thyristor is configured to be in a non-conductive state when the first potential is a ground potential.

6. The memory device as recited in claim 4, wherein the selector thyristor is configured to be in a non-conductive state when the second potential is a ground potential.

7. The method as recited in claim 1, wherein each memory storage component is a resistive random access memory component.

8. The method as recited in claim 7, wherein each memory storage component is a phase change memory component.

9. The memory device as recited in claim 1, wherein the word line conductors are comprised of a material with resistivity greater than 15 μΩ·cm.

10. The memory device as recited in claim 1, wherein the word line conductors are comprised of a material with sheet resistance greater than 1.5Ω/□.

11. The memory device as recited in claim 1, wherein the digit line conductors and the word line conductors are separated by a floating semiconductor region.

12. A method for accessing a memory cell in a cross-point memory array, the method comprising:
selecting the memory cell by applying a first potential to a digit line conductor and applying a second potential to a word line conductor intersecting at the memory cell; and
connecting unselected digit lines and unselected word lines across the array to a return potential while selecting the memory cell.

13. The method of claim 12, wherein selecting comprises triggering a conductive state in a silicon controlled rectifier serving as a selector device for the memory cell.

14. The method of claim 13, wherein triggering comprises applying a triggering potential between an anode and a cathode of the silicon controlled rectifier.

15. The method as recited in claim 14, wherein the information state of the memory storage component that is coupled to the silicon controlled rectifier placed in the conductive state is communicated to a sense circuit.

16. The method of claim 13, wherein triggering comprises
applying a first potential between the digit line conductor and the cathode; and
applying the second potential as a pulse to the word line conductor that is coupled to a gate of the silicon controlled rectifier as a triggering potential to place the silicon controlled rectifier in the conductive state.

17. The method of claim 16, further comprising retrieving an information state from a memory storage component of the memory cell while the silicon controlled rectifier is in the conductive state.

18. The method of claim 17, wherein retrieving an information state from a memory storage component of the memory cell is conducted subsequent to applying the second potential as a pulse.

19. The method of claim 16, further comprising programming an information state to a memory storage component of the memory cell while the silicon controlled rectifier is in the conductive state.

20. The method as recited in claim 16, wherein the thyristor remains in the conductive state following the signal pulse.

21. The method as recited in claim 13, wherein the digit line conductor is coupled to a plurality of memory cells in the array, and wherein triggering comprises applying the first potential to the word line conductor, wherein the word line conductor is coupled to a continuous semiconductor line that forms the gate for a plurality of silicon controlled rectifiers corresponding to the plurality of memory cells.

22. The method as recited in claim 13, wherein each memory cell in the array comprises a phase change memory storage component.

23. An integrated circuit memory device formed on a substrate, the memory device comprising a memory cell formed at the intersection of a word line and a digit line, the memory cell comprising:
a memory storage component having a first node in electrical communication with the digit line and a second node; and
a silicon controlled rectifier (SCR) selector device, comprising:
an anode connected to the second node of the memory storage component,
a floating layer of opposite conductivity type from the anode and forming a junction with the anode,
a gate in electrical communication with the word line, the gate being of opposite conductivity type from the floating layer and forming a junction with the floating layer, and
a cathode of opposite conductivity type from the gate and forming a junction with the gate.

24. A memory device comprising:
a plurality of layers forming a plurality of selector thyristors, wherein each of the plurality of selector thyristors forms a part of a memory cell in an array of memory cells, wherein one of the plurality of layers is a gate layer which is electrically coupled to one of a plurality of word line conductors;
a plurality of digit line conductors, wherein a first node of one of the plurality of resistive memory storage components is coupled to one of the plurality of digit line conductors; and
a plurality of resistive memory storage components, wherein a second node of one of the plurality of resistive memory storage components is coupled to an anode layer of the plurality of layers forming the selector thyristors,
wherein the plurality of word line conductors and the plurality of digit line conductors are arranged in a cross point array.

25. The memory device as recited in claim 24, wherein the gate layer is configured to form a continuous line along a plurality of the selector thyristors, wherein the gate layer is configured to form a gate for the plurality of the selector thyristors, and wherein the gate layer forms at least part of a buried word line conductor of one of the word line conductors.

26. The memory device as recited in claim 24, wherein the plurality of layers comprises four semiconductor layers of alternating conductivity types.

27. The memory device as recited in claim 26, wherein the plurality of layers comprises:
a cathode layer common to memory cells along multiples of the digit line conductors and multiples of the word line conductors;
the gate layer formed over and contacting the cathode layer;
a floating layer formed over and contacting the gate layer; and
the anode layer formed over and contacting the floating layer.

28. The memory device as recited in claim 27, wherein a first plurality of trenches is formed through the anode layer, the floating layer, and the gate layer; and wherein a second plurality of trenches is formed through the anode layer and the floating layer and formed partly through the gate layer.

29. The memory device as recited in claim 28, wherein the first plurality of trenches and the second plurality of trenches are configured to form a continuous buried word line which forms the gate layer of one or more of the selector thyristors, and wherein the continuous buried word line is coupled to one of the word line conductors.

30. The memory device as recited in claim 28, wherein the first plurality of trenches and the second plurality of trenches are configured such that the cathode layer forms a continuous semiconductor layer, and wherein the continuous semiconductor layer forms a cathode for each of the plurality of selector thyristors.

31. The memory device as recited in claim 24, wherein the plurality of word line conductors are formed of a material with resistivity greater than about 15 μΩ·cm.

32. The memory device as recited in claim 24, wherein the plurality of word line conductors are formed of a material with sheet resistance greater than about 1.5Ω/□.
